(19) United States
(12) Patent Application Publication
(10) Pub. No.: US 2026/0237048 A1
(43) Pub. Date: Aug. 13, 2026

(54) METHOD FOR DETERMINING WAFER UNIFORMITY

(71) Applicant: Applied Materials, Inc., Santa Clara, CA (US)

(72) Inventors: Hongwen ZHOU, Pleasanton, CA (US); Qinyi FU, Sunnyvale, CA (US); Luc THOMAS, San Jose, CA (US); Zuoming ZHU, Sunnyvale, CA (US); Erica DE LEON SANCHEZ, San Francisco, CA (US); Abhishek DUBE, Fremont, CA (US)

(73) Assignee: Applied Materials, Inc., Santa Clara, CA (US)

(21) Appl. No.: 19/052,990

(22) Filed: Feb. 13, 2025

(51) Int. Cl. G06T 7/00; G01B 15/02; H01L 21/66; H01L 21/67

(52) U.S. Cl. CPC G06T 7/0004; G01B 15/02; H10P 72/0604; H10P 74/203; G06T 2207/10056; G06T 2207/30148

(57) ABSTRACT

Techniques for measuring uniformity of layer thicknesses on semiconductor wafers are described herein. The techniques can include capturing an image of a portion of a wafer with a transmission electron microscope. The wafer includes a plurality of alternating layers of a first material and a second material. The techniques can include determining pixel intensities across the plurality of alternating layers in the image. The techniques can include fitting the pixel intensities to a model that is descriptive of a trend in the pixel intensities. The techniques can include determining a thickness for a first layer of the wafer based on the model.

### TECHNICAL FIELD

The present technology relates to semiconductor systems, processes, and equipment. More specifically, the present technology relates to processes that deposit multilayer structures on silicon wafers and the metrology for measuring the layer thickness uniformity within the wafer.

### BACKGROUND

Wafers with multilayer structures can be used in the manufacture of logic, memory and storage devices. Example multilayer structures include alternating layers of silicon and silicon germanium. Once a wafer with multilayer structures is manufactured, there may be a need to inspect the uniformity of the layer thickness at multiple points across the wafer. Transmission electron microscopy or other spectroscopic techniques can be used. Transmission electron microscopy measures the layer thickness directly and can be highly reliable if the electron micrographs were acquired at minimal defocus and the pixel size of the electron micrographs was calibrated accurately, while other methods, for example, spectroscopic ellipsometry and X-ray reflectivity rely on building appropriate models to describe the multilayer structures, and may be significantly less reliable when the number of layers increases above 10. However, transmission electron microscopy measurement is a slow process compared to other faster but less reliable methods. Thus, there is a need for fast and reliable method for measuring the uniformity of the layer thickness in a wafer with multilayer structures.

### SUMMARY

In some embodiments, a method of measuring layer thicknesses uniformity on semiconductor wafers can include: capturing an image of a portion of a wafer with a transmission electron microscope, wherein the wafer includes a plurality of alternating layers of a first material and a second material; receiving the image of the portion of the wafer by a computer system; determining, by the computer system, pixel intensities across the plurality of alternating layers in the image; fitting the pixel intensities to a model that is descriptive of a trend in the pixel intensities; and determining a thickness for a first layer of the wafer based on the model.

In some embodiments, a system may include a memory configured to store computer-executable instructions; and one or more processors in communication with the memory and configured to access the memory and execute the computer-executable instructions to: receive the image of a portion of a wafer; determine pixel intensities across the plurality of alternating layers in the image; fit the pixel intensities to a model that is descriptive of a trend in the pixel intensities; and determine a thickness for a first layer of the wafer based on the model.

In some embodiments, one or more non-transitory computer-readable media comprising computer-executable instructions that, when executed by one or more processors of a computer system, cause the one or more processors to perform operations including: receiving the image of the portion of the wafer by a computer system wherein the wafer includes a plurality of alternating layers of a first material and a second material; determining, by the computer system, pixel intensities across the plurality of alternating layers in the image; fitting the pixel intensities to a model that is descriptive of a trend in the pixel intensities; and determining a thickness for a first layer of the wafer based on the model.

In any embodiments, any and all of the following features may be implemented in any combination and without limitation. In some examples, the pixel intensities can be based on an average of pixel intensities along an axis perpendicular to the plurality of alternating layers. In some examples, the method can include normalizing the model by removing background that can be modeled linearly or nonlinearly. In some examples, determining the thickness for a first layer of the wafer can be based on determining a difference between half height points of a peak in the model. In some examples, the thickness of the first material can be between 60 and 70 nanometers. In some examples, determining the thickness of the first layer can have a maximum measurement error of 0.05 nanometers In some examples, the model can include a hyper-Gaussian model. In some examples, the model can include a hyper-Lorentzian model. In some examples, the method may not require determining thickness of the first layer by counting pixels along the thickness of the first layer. In some examples, fitting the pixel intensities to the model can generate a model of a series of peaks and valleys. In some examples, the first material can be silicon, and the second material can be silicon germanium. In some examples, the thickness of the first material can be between 8 and 10 nanometers. In some examples, the portion of the wafer can be a lamella extracted from the wafer, and wherein the image can be an image of an entirety of the lamella. In some examples, fitting the pixel intensities to the model can include determining a best model based on nonlinear regression. In some examples, the method does not require multiple images obtained by transmission electron microscopy. In some examples, the method can include adjusting parameters of a deposition process based at least in part on the thickness for the first layer of the wafer. In some examples, the method can include determining a second thickness for a second layer of the wafer. The second layer can be adjacent to the first layer.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 illustrates a top plan view of one embodiment of a processing system of deposition, etching, baking, and curing chambers that may be included or configured according to some embodiments of the present technology.

FIGS. 2A-2C illustrate diagrams of a multilayer structures in relation to techniques described herein according to some embodiments of the present technology.

FIG. 3 illustrates a diagram of a multilayer wafer in relation to techniques described herein according to some embodiments of the present technology.

FIG. 4 illustrates an example flow diagram for determining wafer uniformity according to some embodiments of the present technology.

FIG. 5 illustrates a diagram of a multilayer wafer in relation to techniques described herein according to some embodiments of the present technology.

FIG. 6 illustrates a diagram of a graph of the integrated pixel intensity projected onto the z-axis according to some embodiments of the present technology.

FIGS. 7A-7E illustrate diagrams of layer thicknesses according to some embodiments of the present technology.

FIG. 8 illustrates an example flow diagram for determining wafer uniformity according to some embodiments of the present technology.

FIG. 9 illustrates an exemplary computer system, in which various embodiments may be implemented.

### DETAILED DESCRIPTION

The present disclosure relates to techniques for determining layer thickness uniformity of wafers used in semiconductor fabrication. Wafers with multilayer structures, for instance, with alternate layers of different materials, can have strict manufacturing requirements and tolerances in order to support different semiconductor technologies and structures. Thin film metrology is used to measure the thickness of the different layers in multilayer wafers. Oftentimes, the layers of materials can be very thin, for example, on the order of nanometers. Fast and precise measurement of the layer thickness in multilayer wafers can monitor chamber drift and identify wafers that do not meet the strict manufacturing requirements and tolerances thus increase yields. However, existing thin film metrology solutions are too imprecise and/or too slow to meet manufacturing requirements and tolerances to support high-volume wafer fabrication.

The techniques described herein can be used to provide a precise and fast way to determine the layer thicknesses of multilayer wafers (or other materials and structures). A transmission electron microscopy (TEM) image of a lamella extracted from the multilayer wafer can be captured. The integrated pixel intensity profile can be measured across the depth of the multilayer structure. The integrated pixel intensity profile can then be fit to a representation (for example, a model). The representation can be used to determine the thickness of each layer in the TEM image.

These techniques have advantages over other thin film metrology methods because fewer TEM images can be used to measure the thickness of tens or hundreds of layers with sufficient precision. The representation can be used to determine the thickness of each layer on the TEM image with high precision. The more conventional TEM measurement technique may rely on taking many TEM images of smaller portions of the multilayer stack. In each of the multiple TEM images, measuring the distance between the upper and lower interfaces of each layer can then be used to determine the actual thickness of each layer. However, capturing multiple TEM images across the entire multilayer stack can require a significant amount of time. The techniques described herein can give about the same precision as a pixel-measuring based approach on multiple TEM images captured at the 10× magnification while being performed as much as twenty times faster. By receiving thin film metrology results more quickly and with adequate precision, yields of multilayer wafers can increase as manufacturing problems and setbacks during wafer production can be detected more quickly.

Although the remaining disclosure will routinely identify specific processes utilizing the disclosed technology, it will be readily understood that the systems and methods are equally applicable to a variety of other processes as may occur in the described chambers. Accordingly, the technology should not be considered to be so limited as for use with the described processes alone. The disclosure will discuss one possible system that can be used with the present technology before describing systems and methods or operations of exemplary process sequences according to some embodiments of the present technology. It is to be understood that the technology is not limited to the equipment described, and processes discussed may be performed in any number of processing chambers and systems.

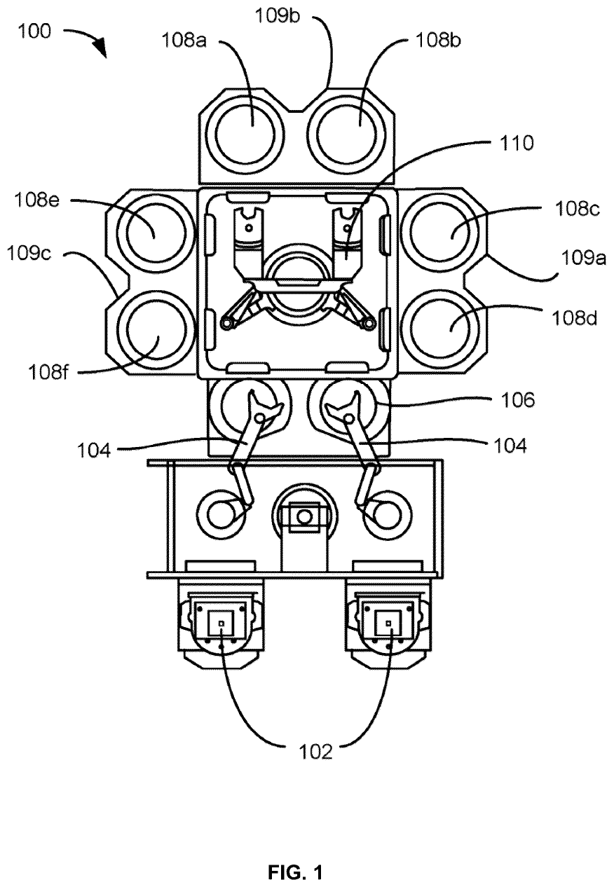

FIG. 1 illustrates a top plan view of one embodiment of a processing system 100 of deposition, etching, baking, and curing chambers that may be included or configured according to some embodiments of the present technology. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f can be outfitted to perform a number of substrate processing operations including the dry etch processes described herein in addition to cyclical layer deposition, atomic layer deposition, chemical vapor deposition, physical vapor deposition, etch, pre-clean, anneal, plasma processing, degas, orientation, and other substrate processes.

The substrate processing chambers 108a-f may include one or more system components for depositing, annealing, curing and/or etching a material film on the substrate or wafer. In one configuration, two pairs of the processing chambers, for example 108c-d and 108e-f, may be used to deposit material on the substrate, and the third pair of processing chambers, for example 108a-b, may be used to cure, anneal, or treat the deposited films. In another configuration, all three pairs of chambers, for example 108a-f, may be configured to both deposit and cure a film on the substrate. Any one or more of the processes described may be carried out in additional chambers separated from the fabrication system shown in different embodiments. It will be appreciated that additional configurations of deposition, etching, annealing, and curing chambers for material films are contemplated by system 100. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

System 100, or more specifically chambers incorporated into system 100 or other processing systems, may be used to produce structures according to some embodiments of the present technology.

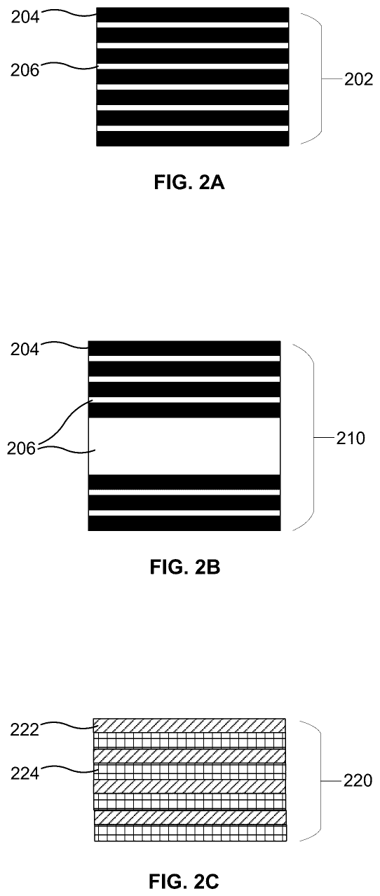

FIG. 2A illustrates a cross section of a multilayer wafer that has a silicon and silicon germanium superlattice structure. The cross section shows a multilayer structure 202 that includes silicon layers 204 and silicon germanium layers 206. In an example, the silicon and silicon germanium superlattice structure can be used for a three-dimensional dynamic random access memory (3D DRAM). A silicon and silicon germanium superlattice structure used for a 3D DRAM may have between 8 and 80 (or more) pairs of silicon layers 204 and silicon germanium layers 206. In this example, the silicon layers 204 may be significantly thicker than the silicon germanium layers 206. For example, the silicon layers 204 can be about 70 nanometers thick while the silicon germanium layers 206 can be about 10 nanometers thick. In an example, the silicon and silicon germanium superlattice structure can be used for gate all around field effect transistors (GAAFETs). A silicon germanium superlattice structure used for GAAFETs may have a few pairs (for example, 3 or 4) of silicon layers 204 and silicon germanium layers 206. In this example, the silicon layers 204 and the silicon germanium layers 206 can be about the same thickness. For example, the silicon layers 204 and the silicon germanium layers 206 can be between 8 and 10 nanometers thick.

FIG. 2B illustrates a cross section of a multilayer wafer that can be used for complementary field effect transistors (cFETs). In this example, the multilayer structure 210 can include two GAAFET structures that are vertically stacked and separated by a thick silicon germanium middle layer as seen in FIG. 2B.

FIG. 2C illustrates a cross section of a multilayer wafer that can be used for a three dimensional NAND flash memory. In one example, the multilayer structure 220 can include silicon oxide layers 222 and silicon nitride layers 224. This multilayer structure 220 can be referred to as an ONO stack. An ONO stack may have between a few and hundreds of pairs of silicon oxide layers 222 and silicon nitride layers 224. For example, an ONO stack may have between 32 and 300 pairs of silicon oxide layers 222 and silicon nitride layers 224. In another example, the multilayer structure 220 can include silicon oxide layers 222 and amorphous silicon layers 224. This multilayer structure 220 can be referred to as an OPO stack. An OPO stack may have between a few and hundreds of pairs of silicon oxide layers 222 and amorphous silicon layers 224. For example, an OPO stack may have between 32 and 300 pairs of silicon oxide layers 222 and amorphous silicon layers 224. Any of the stacks illustrated in FIGS. 2A-2C are compatible with the techniques described below.

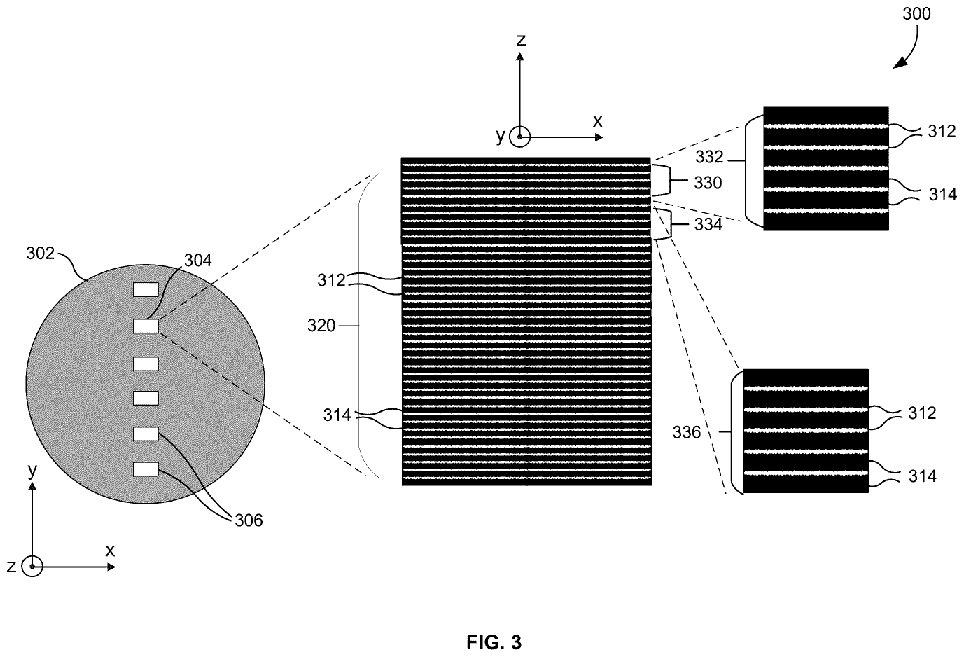

FIG. 3 illustrates a diagram 300 of a wafer with a multilayer structure. This diagram can be used to illustrate some methods for determining layer thickness uniformity of wafers using transmission electron microscopy (TEM). The multilayer wafer 302 can include layers of different materials. In some examples, a multilayer wafer 302 can include layers of two different materials which alternate. Example multilayer wafers are described in relation to FIGS. 2A-2C. In some examples, a multilayer wafer 302 can include layers of multiple different materials which can be arranged in a variety of sequences. For example, the multilayer stack can include three or more materials deposited in a repeating or non-repeating sequence.

TEM can be used for thin film metrology of the wafer 302. A TEM lamella 320 (for example, a thin slice of the wafer that can be about a few microns in length, a few microns in height, and tens or hundreds of nanometers in thickness, such as 10 μm×10 μm×0.1 μm) can be extracted from the wafer 302 (for example at location 304 or multiple locations 306). The TEM lamella 320 can include alternating layers of a first material 312 and a second material 314. In some examples, the first material 312 can be silicon germanium. In some examples, the second material 314 can be silicon. In some examples, the first material 312 can be silicon oxide. In some examples, the second material 314 can be silicon nitride. In some examples, the first material 312 can be silicon oxide. In some examples, the second material 314 can be amorphous silicon. For example, silicon and silicon germanium can be used for gate-all-around field-effect-transistors (GAAFETs), complementary field-effect-transistors (cFETs) or three-dimensional dynamic random access memory (3D-DRAM), and silicon oxide and silicon nitride can be used for three-dimensional NAND flash memory and silicon oxide and amorphous silicon can be used for three-dimensional NAND flash memory.

Some methods for determining layer thickness uniformity of wafers using TEM may use high magnification scanning transmission electron microscopy (STEM) images. For example, a first image 332 and a second image 336 can be generated by performing STEM on a first portion 330 and a second portion 334 of the lamella 320, respectively. Pixel intensities of a STEM image can be proportional to the number of electrons that were scattered by the materials under the scanning electron beam and then collected by the high-angle annular dark-field detector (HAADF). There are also other mechanisms that account for the pixel intensity contrast. However, in each of the mechanisms for determining pixel intensities, the differences in pixel intensities may indicate a difference in material density. In this example, the first image 332 and the second image 336 show layers of the first material 312 and layers of the second material 314.

The thickness of layers of the first material 312 and the thickness of layers of the second material 314 can be determined by counting the number of pixels of each layer along the thickness direction (z-axis). The electron micrograph can be calibrated in order to translate pixels into physical distances. The resolution of the portion 332 and the portion 336 can be sufficiently high to determine the thickness of layers within a margin of error based on the pixel size. The thickness of the layers can be determined by drawing a line perpendicular to the layer. The length of the line can then be translated from a pixel length to a physical length. This method of determining the thickness of the layers can be referred to as a pixel counting approach. The precision of a pixel counting approach to determine the layer thickness is limited by the pixel size. Thus, the precision of the thickness measurement from the high magnification first image 332 and second image 336 is based on the pixel size of the first image 332 and the second image 336.

However, capturing a series of high magnification TEM or STEM images (for example, the first image 332 and the second image 336) to include all layers of the lamella 320 can take a significant amount of time. Furthermore, analysis of the high magnification TEM images to determine layer thickness by the pixel counting method can take significant time. The pixel counting method can also introduce human error as a person typically determines the point where a layer begins and ends. The techniques described herein enable the low magnification TEM image to be used to determine the thickness of the layers of the first material 312 and the second material 314 and provide a similar level of precision to using a pixel counting method on higher magnification TEM images.

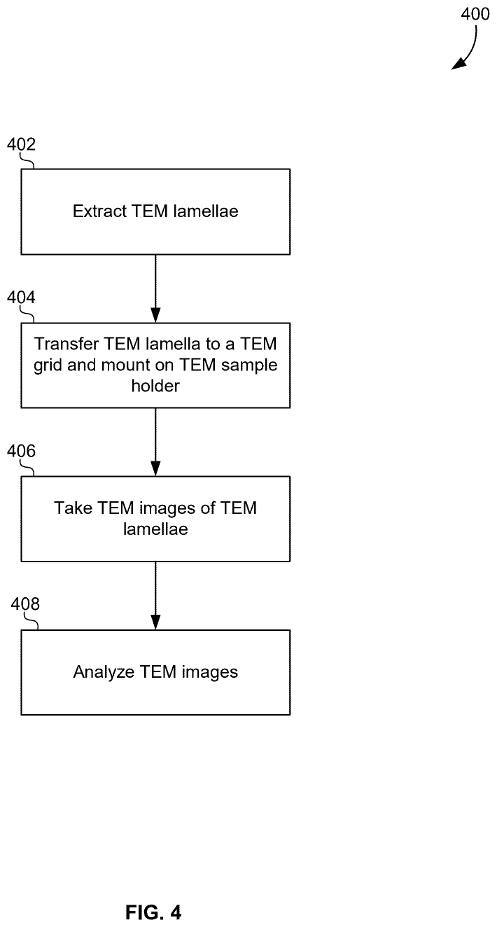

FIG. 4 illustrates a process 400 for determining layer thickness uniformity of wafers using TEM or STEM. The process 400 can begin at block 402 by extracting TEM lamella from a wafer. TEM lamella can be cut from the wafer using a focused ion beam (FIB) instrument. In some examples, the TEM lamella can be extracted along a diameter of a wafer. Prior to extracting the TEM lamella from a wafer, one or more spots on the wafer can be marked to be studied by TEM. In some examples, extracting the TEM lamella from a wafer is destructive such that the wafer may not be usable for further processing and manufacture of semiconductor devices.

The process 400 can also include block 404 where the TEM lamella are transferred to a TEM grid and mounted on a TEM sample holder. The TEM grid can include mesh holes and one or more TEM lamella can be placed on one of the mesh holes of the TEM grid. The TEM grid can then be mounted at the tip of a TEM sample holder for insertion into the TEM for imaging. The process 400 can include block 406 where the TEM takes TEM or STEM images of the lamella mounted at the tip of a TEM sample holder. The process 400 can include block 408 where the TEM or STEM images are then analyzed via the techniques described herein.

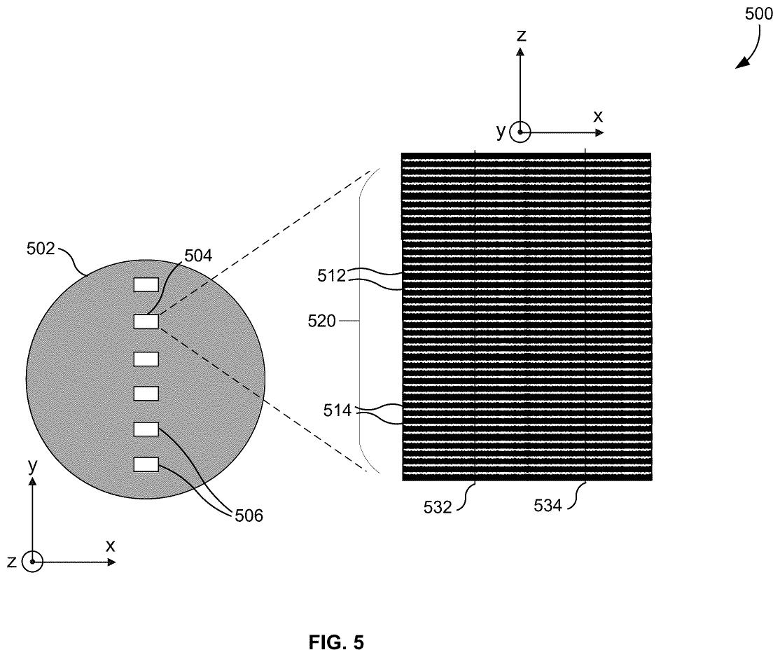

FIG. 5 illustrates a diagram 500 of a wafer with a multilayer structure. This diagram can be used to illustrate some methods for determining layer thickness uniformity of wafers using TEM and analysis methods. The multilayer wafer 302 can include layers of different materials. In some examples, a multilayer wafer 302 can include layers of two different materials which alternate. Example multilayer wafers are described in relation to FIGS. 2A-2C. In some examples, a multilayer wafer 302 can include layers of multiple different materials which can be arranged in a variety of sequences. For example, the multilayer stack can consist of three or more materials deposited in a repeating or non-repeating sequence.

TEM can be used for thin film metrology of the wafer 302. A TEM lamella 504 (for example, a thin slice of the wafer that can be a few microns in length, a few microns in height, and tends to hundreds of nanometers in thickness, such as 10 μm×10 μm×0.1 μm) can be extracted from the wafer 302 (for example at locations 506). The TEM lamella 504, depicted in the TEM image 520, can include alternating layers of a first material 312 and a second material 314. In some examples, the first material 312 can be silicon germanium. In some examples, the second material 314 can be silicon. In some examples, the first material 312 can be silicon oxide. In some examples, the second material 314 can be silicon nitride. In some examples, the first material 312 can be silicon oxide. In some examples, the second material 314 can be amorphous silicon. For example, silicon and silicon germanium can be used for gate-all-around field-effect-transistors (GAAFETs), complementary field-effect-transistors (cFETs) or three-dimensional dynamic random access memory (3D-DRAM), and silicon oxide and silicon nitride can be used for three-dimensional NAND flash memory and silicon oxide and amorphous silicon can be used for three-dimensional NAND flash memory.

The primary purpose of the thin film metrology of the wafer 502 is to determine the thickness of individual layers. In the first image 520, the thickness is the vertical dimension of the layer. The horizontal dimension of the first image 520 represent the field of view of the acquired image. The TEM image 520 represents an image taken via TEM (also referred to herein as a TEM image) for TEM lamella 504. The TEM image 520 can be generated by performing TEM on a TEM lamella 504 extracted from the wafer 502. The TEM image 520 can be taken at a low magnification such that a significant portion of the TEM lamella 504, a majority of the TEM lamella 504, or all of the TEM lamella 504 can be captured in the TEM image 520. The techniques described herein enable the TEM image 520, which is relatively low magnification, to be used to determine the thickness of the layers of the first material 512 and the second material 514 and provide a similar level of precision to using a pixel counting method on higher magnification TEM images. In some examples, the low magnification TEM image 520 can include layers from twenty or more at high magnification as the first image 332 and the second image 336 of FIG. 3. In this way, the imaging time for taking the low magnification TEM or STEM image 520 may be a tenth of the imaging time for twenty images that are at high magnification as the first image 332 and the second image 336 of FIG. 3.

Instead of using the pixel counting method on the TEM image 520, pixel intensities of the TEM image 520 are measured to create a one-dimensional integrated pixel intensity profile. Pixel intensity of a TEM image 520 is a measure of the brightness of the pixel. For example as shown in FIG. 5, pixel intensities can be taken along lines 532, 534. These pixel intensities can be indicative of the material. For example, the pixel intensities of the first material 512 in the TEM image 520 are higher than the pixel intensities of the second material 514 in the TEM image 520. There is a difference in pixel intensities that are indicative of the different materials.

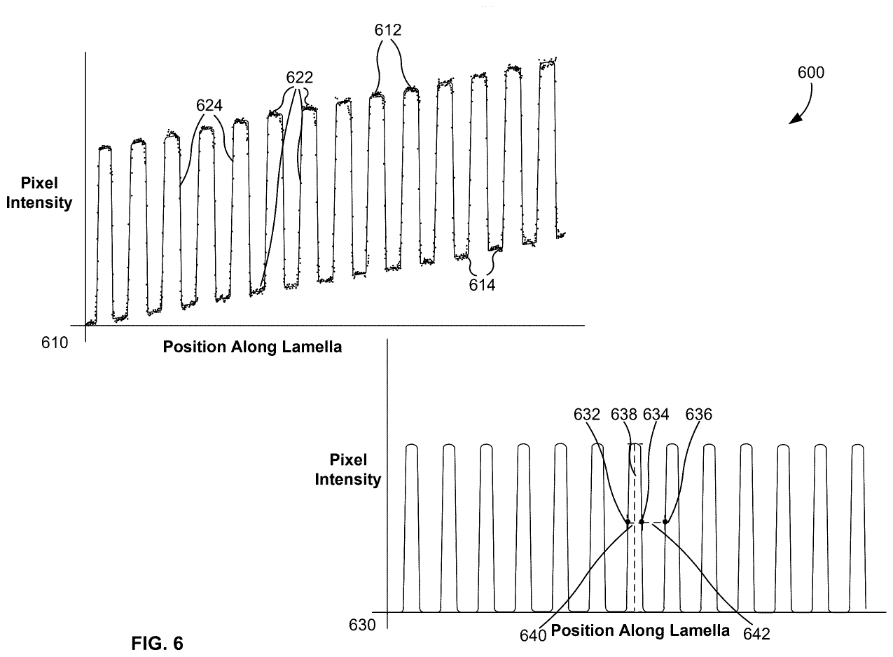

In some examples, the pixel intensities are used to generate a one-dimensional integrated pixel intensity profile along the z-axis. The integrated pixel intensity profile represents the pixel intensity profile averaged over all x-coordinates (the width of the TEM lamella 504 as seen in the TEM image 520). For example, an average pixel intensity can be calculated based on all pixels with a particular z-axis coordinate regardless of the x-axis coordinate. Then the average pixel intensity can be used as the pixel intensity from which a representation is generated. In some examples, the representation can be a graph of the integrated pixel intensity profile. The integrated pixel intensity profile can then be plotted on a graph as shown in FIG. 6.

In the example where the first material 512 is silicon germanium, the thickness of each layer can be less than or about 100.00 nm. In some examples, the thickness of each silicon germanium layer can be less than or about 95.00 nm, less than or about 90.00 nm, less than or about 85.00 nm, less than or about 80.00 nm, less than or about 75.00 nm, less than or about 70.00 nm, less than or about 65.00 nm, less than or about 60.00 nm, less than or about 55.00 nm, less than or about 50.00 nm, less than or about 45.00 nm, less than or about 40.00 nm, less than or about 35.00 nm, less than or about 30.00 nm, less than or about 25.00 nm, less than or about 20.00 nm, less than or about 15.00 nm, less than or about 10.00 nm, less than or about 5.00 nm, or less. In some examples, the thickness of each layer of silicon germanium can be slightly different within a manufacturing tolerance.

In the example where the second material 514 is silicon, the thickness of each layer can be less than or about 300.00 nm. In some examples, the thickness of each silicon layer can be less than or about 295.00 nm, less than or about 290.00 nm, less than or about 285.00 nm, less than or about 280.00 nm, less than or about 275.00 nm, less than or about 270.00 nm, less than or about 265.00 nm, less than or about 260.00 nm, less than or about 255.00 nm, less than or about 250.00 nm, less than or about 245.00 nm, less than or about 240.00 nm, less than or about 235.00 nm, less than or about 230.00 nm, less than or about 225.00 nm, less than or about 220.00 nm, less than or about 215.00 nm, less than or about 210.00 nm, less than or about 205.00 nm, less than or about 200.00 nm, less than or about 195.00 nm, less than or about 190.00 nm, less than or about 185.00 nm, less than or about 180.00 nm, less than or about 175.00 nm, less than or about 170.00 nm, less than or about 165.00 nm, less than or about 160.00 nm, less than or about 155.00 nm, less than or about 150.00 nm, less than or about 145.00 nm, less than or about 410.00 nm, less than or about 135.00 nm, less than or about 130.00 nm, less than or about 125.00 nm, less than or about 120.00 nm, less than or about 115.00 nm, less than or about 110.00 nm, less than or about 105.00 nm, less than or about 100.00 nm, less than or about 95.00 nm, less than or about 90.00 nm, less than or about 85.00 nm, less than or about 80.00 nm, less than or about 75.00 nm, less than or about 70.00 nm, less than or about 65.00 nm, less than or about 60.00 nm, less than or about 55.00 nm, less than or about 50.00 nm, less than or about 45.00 nm, less than or about 40.00 nm, less than or about 35.00 nm, less than or about 30.00 nm, less than or about 25.00 nm, less than or about 20.00 nm, less than or about 15.00 nm, less than or about 10.00 nm, less than or about 5.00 nm, or less. In some examples, the thickness of each layer of silicon can be slightly different within a manufacturing tolerance.

FIG. 6 illustrates a diagram 600 including a first graph 610 of pixel intensities (also referred to as a one-dimensional integrated pixel intensity profile) along the z-axis of a wafer (for example, wafer 502 of FIG. 5). First, the individual pixel intensities 622 are plotted against the position along the lamella extracted from the wafer. In some examples, a lamella is extracted from the wafer and the lamella is examined via TEM to produce the TEM images described herein. The position along the lamella can be determined by using the calibration of the TEM to approximate the physical location represented by a pixel. Pixel intensity can refer to the brightness of the pixel. For example, a white pixel will have higher pixel intensity than a gray pixel. A standard scale for pixel intensity can be used.

Then a representation 624 of the pixel intensities can be determined based on the plotted pixel intensities (raw data) as seen in graph 610. For example, the pixel intensities can be modeled by an equation (also referred to as a trend or a model). These equations can also be referred to as fitting functions.

In some examples, the equation for modeling the pixel intensities can be an asymmetric hyper-Gaussian function. In an asymmetric hyper-Gaussian function form of the equation, the pixel intensity can be related to a summation of sub-equations associated with each layer of one of the two materials (for example, the silicon germanium layers). Each sub-equation associated with each layer can be related to the amplitude of the layer, the position of a pixel of the image in relation to the centers of a peak associated with the layer, parameters that define the peak width, and an asymmetric factor. In some examples, the equation for modeling the pixel intensities can be an asymmetric hyper-Lorentzian function. In an asymmetric hyper-Lorentzian function form of the equation, the pixel intensity can be related to a summation of sub-equations associated with each layer of one of the two materials (for example, the silicon germanium layers). Each sub-equation associated with each layer can be related to the amplitude of the layer, the position of a pixel of the image in relation to the centers of a peak associated with the layer, parameters that define the peak width, and an asymmetric factor. Some parameters that define the peak widths can relate to plateau-shaped peaks and triangle-shaped peaks. Additionally, the asymmetric factor can be used to address the different interface roughness at the peaks 612 for each layer. The equation can also include a “background” portion as described below. The best equation that matches to the plotted pixel intensities can be determined via nonlinear regression. In some examples, the nonlinear regression can be Levenberg-Marquardt nonlinear regression. The nonlinear regression can be used to determine an equation that models the plotted pixel intensities the best by finding the best equation that has the least residue. As seen in FIG. 3, the graph 610 can be characterized as a series of peaks 612 alternating with valleys 614.

Once an equation (for example, the best fitting equation) has been determined for the pixel intensities 622, the graph 610 can be normalized by extracting the “background” portions of the best fitting equation. In some examples, the background portions can be represented by a linear equation. In other examples, the background portion can be represented by a non-linear equation such as a polynomial, exponential, or logarithmic equation. Normalizing the graph 610 can be used to generate graph 620. The height 638 of each peak can be determined and used to determine the half height points on either side of the peak. The half height points 632 and 634 can be separated by a difference 640. The difference 640 can also be referred to the full-width-at-half-maximum (FWHM). The difference 640 can be the thickness of the corresponding layer of material. Similarly, the height of the adjacent peak can be determined and used to determine half height points on either side of the peak, including half height point 636. The half height points 634 and 636 can be separated by a difference 642. The difference 642 can be the thickness of the corresponding layer of material.

By using an equation to model the pixel intensities and then determining half height points, a thickness of a layer can be determined by a fraction of a pixel. This enables the use of a single lower magnification TEM or STEM image rather than a series of higher magnification TEM or STEM images. For example, pixel intensities from the TEM or STEM image 520 of FIG. 5 can be used to generate a graph like graph 610. The graph 610 can then be normalized to generate a graph like graph 620. Then the half height points for each peak can be determined in order to calculate the thickness of each layer.

Once the representation 624 is determined, the x coordinates of each peak at the half maximum is calculated from the fitting function. The peak width 640 (based on the full-width-at-half-maximum) is determined by (zᵢ)_{right}−(zᵢ)_{left} which corresponds to the silicon germanium layer thickness. For example, one peak width can be determined as the distance along the z-axis between a first point 632 and a second point 634. The valley width 642 (based on the full-width-at-half-maximum) is determined by (zᵢ)_{left}−(zᵢ₋₁)_{right} which corresponds to the silicon layer thickness. For example, one valley width can be determined as the distance along the z-axis of the wafer between a second point 634 and a third point 636. The measurement error for the silicon germanium layer thickness and the silicon layer thickness is approximately the same as when higher magnification TEM or STEM images with smaller fields-of-view are used with a pixel counting approach.

In the example where the first material 612 is silicon germanium, the measurement error for the thickness of each silicon germanium layer can be less than or about 0.30 nm. In some examples, the measurement error for the thickness of each layer can be less than or about 0.29 nm, less than or about 0.28 nm, less than or about 0.27 nm, less than or about 0.26 nm, less than or about 0.25 nm, less than or about 0.24 nm, less than or about 0.23 nm, less than or about 0.22 nm, less than or about 0.21 nm, less than or about 0.20 nm, less than or about 0.19 nm, less than or about 0.18 nm, less than or about 0.17 nm, less than or about 0.16 nm, less than or about 0.15 nm, less than or about 0.14 nm, less than or about 0.13 nm, less than or about 0.12 nm, less than or about 0.11 nm, less than or about 0.10 nm, less than or about 0.09 nm, less than or about 0.08 nm, less than or about 0.07 nm, less than or about 0.06 nm, less than or about 0.05 nm, or less.

In the example where the second material 614 is silicon, the measurement error for the thickness of each silicon layer can be less than or about 0.30 nm. In some examples, the measurement error for the thickness of each layer can be less than or about 0.29 nm, less than or about 0.28 nm, less than or about 0.27 nm, less than or about 0.26 nm, less than or about 0.25 nm, less than or about 0.24 nm, less than or about 0.23 nm, less than or about 0.22 nm, less than or about 0.21 nm, less than or about 0.20 nm, less than or about 0.19 nm, less than or about 0.18 nm, less than or about 0.17 nm, less than or about 0.16 nm, less than or about 0.15 nm, less than or about 0.14 nm, less than or about 0.13 nm, less than or about 0.12 nm, less than or about 0.11 nm, less than or about 0.10 nm, less than or about 0.09 nm, less than or about 0.08 nm, less than or about 0.07 nm, less than or about 0.06 nm, less than or about 0.05 nm, or less.

In some examples, the pixel intensity that is plotted on the graph is a pixel intensity averaged for some or all pixels in the x-direction at a particular z-coordinate of the TEM image. For example, an average pixel intensity can be calculated based on some or all pixels with a z-coordinate of 10 regardless of the length coordinate. Then the average pixel intensity can be used as the pixel intensity 622 from which the representation 624 is generated. In some examples, the pixel intensities plotted on the graph are an average pixel intensity along an axis perpendicular to the alternating layers of material.

The thickness of different layers can be used for many purposes. For example, the thicknesses of the different layers can be used to determine that adjustments need to be made to a deposition process. In another example, the thicknesses of the different layers can be used to determine how deposition process needs to be adjusted.

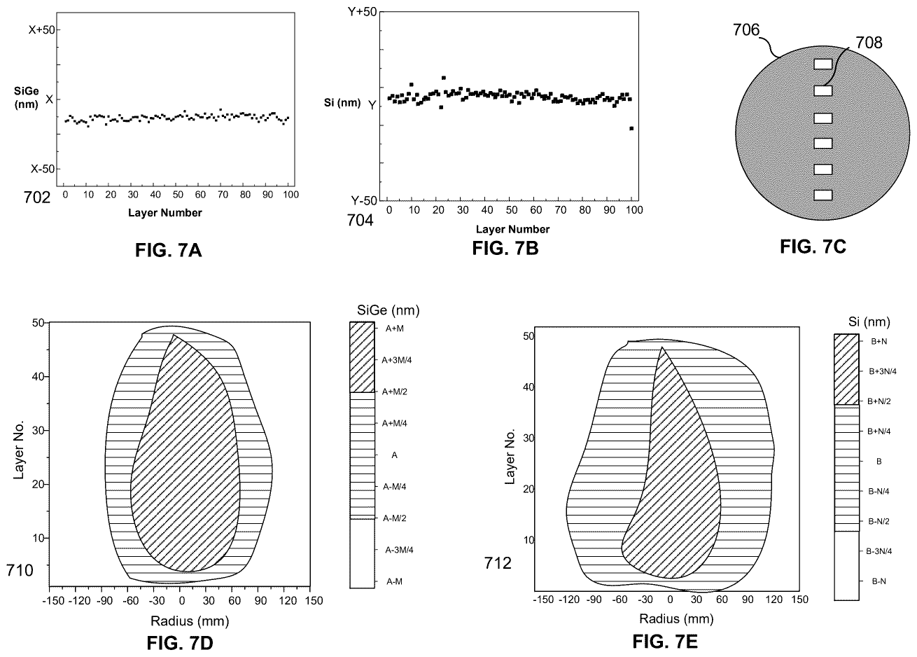

FIG. 7A illustrates an example graph 702 which shows the layer thickness of each layer of silicon germanium (or any first material) as determined from the full-width-at-half-maximum of the peaks shown in graph 630 of FIG. 6. The graph 702 can be used to determine any trends or abnormalities in the thickness of each layer of silicon germanium. Similarly, FIG. 7B illustrates an example graph 704 which shows the layer thickness of each layer of silicon (or any second material) as determined from the full-width-at-half-maximum of the valleys shown in graph 630 of FIG. 6. The graph 704 can be used to determine any trends or abnormalities in the thickness of each layer of silicon. The graphs 702, 704 indicate the layer thicknesses of particular layers of each material in one of the lamella 708 extracted from the wafer 706 shown in FIG. 7C. The graphs 702, 704 can be used to determine if there are abnormalities in the wafer 706 at the location where the lamella 708 was extracted from the wafer 706.

Multiple graphs similar to graphs 702, 704 can be generated for each lamella 708 extracted from the wafer 706. In some examples, multiple lamellae 708 can be extracted from the wafer 706. For example, any suitable number of lamellae 708 can be extracted from the wafer 706. Example number of lamellae 708 that can be extracted from the wafer 706 can range from one lamella 708 to 100 lamellae 708. The lamella 708 can also correspond to specific locations on the wafer, for example a distance from the center of the wafer 706. The lamellae 708 can be along an axis of the wafer 706. The graphs 702 for each lamella can be combined to form an example heat map 710 as shown in FIG. 7D. The heat map 710 can show the thickness of layers across multiple lamellae. For example, the heat map 710 can show the thickness of silicon germanium layers at different layer numbers and along an axis of the wafer 706. Similarly, the graphs 704 for each lamella can be combined to form an example heat map 712 as shown in FIG. 7E. For example, the heat map 712 can show the thickness of silicon layers at different layer numbers and along an axis of the wafer 706. The heat maps 710, 712 can be used to determine if the wafer has layer thicknesses that are outside of the expected range.

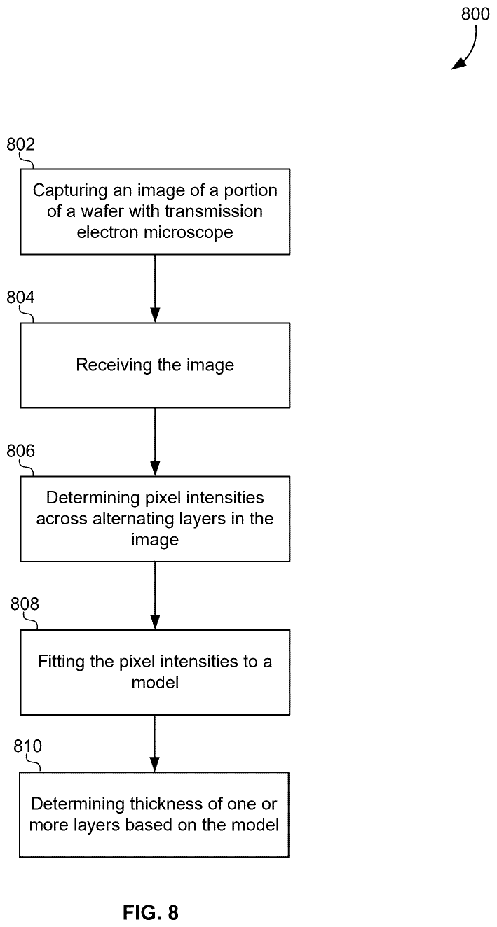

FIG. 8 illustrates a flowchart of exemplary operations in a process 800 of determining layer thickness according to some embodiments of the present technology. Determining layer thickness can also be referred to as determining wafer uniformity. Method 800 may include one or more operations prior to the initiation of the method 800. Method 800 may include a number of optional operations, which may or may not be specifically associated with some embodiments of methods according to embodiments of the present technology.

It should be appreciated that the specific steps illustrated in FIG. 8 provide particular methods of determining layer thickness according to various embodiments. Other sequences of steps may also be performed according to alternative embodiments. For example, alternative embodiments may perform the steps outlined above in a different order. Moreover, the individual steps illustrated in FIG. 8 may include multiple sub-steps that may be performed in various sequences as appropriate to the individual step. Furthermore, additional steps may be added or removed depending on the particular applications. Many variations, modifications, and alternatives also fall within the scope of this disclosure.

At operation 802, an image of a portion of a wafer can be captured with a transmission electron microscope. The wafer can include a plurality of alternating layers of a first material and a second material. The first material can be silicon. The second material can be silicon germanium. The portion of the wafer can be a lamella extracted from the wafer. The image can be an image of an entirety of the lamella.

At operation 804, the image of the portion of the wafer can be received. In some examples, a computer system receives the image. At operation 806, pixel intensities across the plurality of alternating layers in the image can be determined. In some examples, a computer system can determine the pixel intensities. The set of pixel intensities can be based on an average of pixel intensities along an axis perpendicular to the plurality of alternating layers.

At operation 808, the pixel intensities can be fit to a model that is descriptive of a trend in the pixel intensities. In some examples, a computer system can fit the pixel intensities to the model. In some examples, the model includes a hyper-Lorentzian model. In some examples, the model includes a hyper-Gaussian model. Fitting the pixel intensities to the model can generate a model of a series of peaks and valleys. Fitting the pixel intensities to the model can include determining a best model based on nonlinear regression.

At operation 810, a thickness for a first layer of the wafer can be determined based on the model. In some examples, a computer system can determine the thickness for the first layer of the wafer. In some examples, determining the thickness for a first layer of the wafer can be based on determining a difference between half height points of a peak in the model. In some examples, determining the thickness of the second layer can have a maximum measurement error of 0.15 nanometers.

The process 800 can further include normalizing the model by removing background that can be modeled linearly. In some examples, the thickness of the first material can be about 60 nanometers. In some examples, the thickness of the first material can be about 9 nanometers. The process 800 may not require multiple images obtained by transmission electron microscopy. The process 800 may not require determining thickness of the first layer by counting pixels along the thickness direction of the first layer. The process 800 can further include adjusting parameters of a deposition process based at least in part on the thickness for the first layer of the wafer. The process 800 can further include determining a second thickness for a second layer of the wafer. The second layer can be adjacent to the first layer.

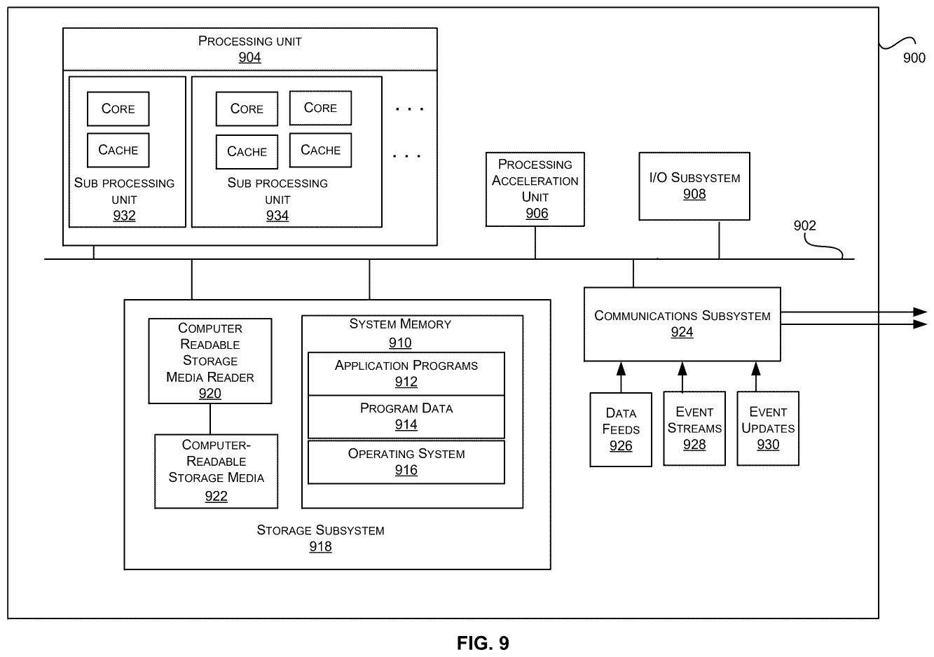

FIG. 9 illustrates an exemplary computer system 900, in which various embodiments may be implemented. For example, the process 800 of FIG. 8 may include operations that may be executed by the computer system 900. As described below, the computer system 900 may include one or more processors and one or more memory devices. The memory devices may include one or more non-transitory computer-readable media that store instructions for the processor(s). These instructions, when executed by the processor(s), may cause the processor(s) to perform any of the operations of any of the processes described above. As shown in the figure, computer system 900 includes a processing unit 904 that communicates with a number of peripheral subsystems via a bus subsystem 902. These peripheral subsystems may include a processing acceleration unit 906, an I/O subsystem 908, a storage subsystem 918 and a communications subsystem 924. Storage subsystem 918 includes tangible computer-readable storage media 922 and a system memory 910.

Bus subsystem 902 provides a mechanism for letting the various components and subsystems of computer system 900 communicate with each other as intended. Although bus subsystem 902 is shown schematically as a single bus, alternative embodiments of the bus subsystem may utilize multiple buses. Bus subsystem 902 may be any of several types of bus structures including a memory bus or memory controller, a peripheral bus, and a local bus using any of a variety of bus architectures. For example, such architectures may include an Industry Standard Architecture (ISA) bus, Micro Channel Architecture (MCA) bus, Enhanced ISA (EISA) bus, Video Electronics Standards Association (VESA) local bus, EtherCAT, and Peripheral Component Interconnect (PCI) bus, which can be implemented as a Mezzanine bus manufactured to the IEEE P1386.1 standard.

Processing unit 904, which can be implemented as one or more integrated circuits (e.g., a conventional microprocessor or microcontroller), controls the operation of computer system 900. One or more processors may be included in processing unit 904. These processors may include single core or multicore processors. In certain embodiments, processing unit 904 may be implemented as one or more independent processing units 932 and/or 934 with single or multicore processors included in each processing unit. In other embodiments, processing unit 904 may also be implemented as a quad-core processing unit formed by integrating two dual-core processors into a single chip.

In various embodiments, processing unit 904 can execute a variety of programs in response to program code and can maintain multiple concurrently executing programs or processes. At any given time, some or all of the program code to be executed can be resident in processor(s) 904 and/or in storage subsystem 918. Through suitable programming, processor(s) 904 can provide various functionalities described above. Computer system 900 may additionally include a processing acceleration unit 906, which can include a digital signal processor (DSP), a special-purpose processor, and/or the like.

I/O subsystem 908 may include user interface input devices and user interface output devices. User interface input devices may include a keyboard, pointing devices such as a mouse or trackball, a touchpad or touch screen incorporated into a display, a scroll wheel, a click wheel, a dial, a button, a switch, a keypad, audio input devices with voice command recognition systems, microphones, and other types of input devices.

User interface output devices may include a display subsystem, indicator lights, or non-visual displays such as audio output devices, etc. The display subsystem may be a cathode ray tube (CRT), a flat-panel device, such as that using a liquid crystal display (LCD) or plasma display, a projection device, a touch screen, and the like. In general, use of the term “output device” is intended to include all possible types of devices and mechanisms for outputting information from computer system 900 to a user or other computer. For example, user interface output devices may include, without limitation, a variety of display devices that visually convey text, graphics and audio/video information such as monitors, printers, speakers, headphones, automotive navigation systems, plotters, voice output devices, and modems.

Computer system 900 may comprise a storage subsystem 918 that comprises software elements, shown as being currently located within a system memory 910. System memory 910 may store program instructions that are loadable and executable on processing unit 904, as well as data generated during the execution of these programs.

Depending on the configuration and type of computer system 900, system memory 910 may be volatile (such as random access memory (RAM)) and/or non-volatile (such as read-only memory (ROM), flash memory, etc.) The RAM typically contains data and/or program modules that are immediately accessible to and/or presently being operated and executed by processing unit 904. In some implementations, system memory 910 may include multiple different types of memory, such as static random access memory (SRAM) or dynamic random access memory (DRAM). In some implementations, a basic input/output system (BIOS), containing the basic routines that help to transfer information between elements within computer system 900, such as during start-up, may typically be stored in the ROM. By way of example, and not limitation, system memory 910 also illustrates application programs 912, which may include client applications, Web browsers, mid-tier applications, relational database management systems (RDBMS), etc., program data 914, and an operating system 916.

Storage subsystem 918 may also provide a tangible computer-readable storage medium for storing the basic programming and data constructs that provide the functionality of some embodiments. Software (programs, code modules, instructions) that when executed by a processor provide the functionality described above may be stored in storage subsystem 918. These software modules or instructions may be executed by processing unit 904. Storage subsystem 918 may also provide a repository for storing data used in accordance with some embodiments.

Storage subsystem 900 may also include a computer-readable storage media reader 920 that can further be connected to computer-readable storage media 922. Together and, optionally, in combination with system memory 910, computer-readable storage media 922 may comprehensively represent remote, local, fixed, and/or removable storage devices plus storage media for temporarily and/or more permanently containing, storing, transmitting, and retrieving computer-readable information.

Computer-readable storage media 922 containing code, or portions of code, can also include any appropriate media, including storage media and communication media, such as but not limited to, volatile and non-volatile, removable and non-removable media implemented in any method or technology for storage and/or transmission of information. This can include tangible computer-readable storage media such as RAM, ROM, electronically erasable programmable ROM (EEPROM), flash memory or other memory technology, CD-ROM, digital versatile disk (DVD), or other optical storage, magnetic cassettes, magnetic tape, magnetic disk storage or other magnetic storage devices, or other tangible computer readable media. This can also include nontangible computer-readable media, such as data signals, data transmissions, or any other medium which can be used to transmit the desired information, and which can be accessed by computing system 900.

By way of example, computer-readable storage media 922 may include a hard disk drive that reads from or writes to non-removable, nonvolatile magnetic media, a magnetic disk drive that reads from or writes to a removable, nonvolatile magnetic disk, and an optical disk drive that reads from or writes to a removable, nonvolatile optical disk such as a CD ROM, DVD, and Blu-Ray® disk, or other optical media. Computer-readable storage media 922 may include, but is not limited to, Zip® drives, flash memory cards, universal serial bus (USB) flash drives, secure digital (SD) cards, DVD disks, digital video tape, and the like. Computer-readable storage media 922 may also include, solid-state drives (SSD) based on non-volatile memory such as flash-memory based SSDs, enterprise flash drives, solid state ROM, and the like, SSDs based on volatile memory such as solid state RAM, dynamic RAM, static RAM, DRAM-based SSDs, magnetoresistive RAM (MRAM) SSDs, and hybrid SSDs that use a combination of DRAM and flash memory based SSDs. The disk drives and their associated computer-readable media may provide non-volatile storage of computer-readable instructions, data structures, program modules, and other data for computer system 900.

Communications subsystem 924 provides an interface to other computer systems and networks. Communications subsystem 924 serves as an interface for receiving data from and transmitting data to other systems from computer system 900. For example, communications subsystem 924 may enable computer system 900 to connect to one or more devices via the Internet. In some embodiments communications subsystem 924 can include radio frequency (RF) transceiver components for accessing wireless voice and/or data networks (e.g., using cellular telephone technology, advanced data network technology, such as 3G, 4G or EDGE (enhanced data rates for global evolution), WiFi (IEEE 802.11 family standards, or other mobile communication technologies, or any combination thereof), global positioning system (GPS) receiver components, and/or other components. In some embodiments communications subsystem 924 can provide wired network connectivity (e.g., Ethernet) in addition to or instead of a wireless interface.

In some embodiments, communications subsystem 924 may also receive input communication in the form of structured and/or unstructured data feeds 926, event streams 928, event updates 930, and the like on behalf of one or more users who may use computer system 900.

Additionally, communications subsystem 924 may also be configured to receive data in the form of continuous data streams, which may include event streams 928 of real-time events and/or event updates 930, that may be continuous or unbounded in nature with no explicit end. Examples of applications that generate continuous data may include, for example, sensor data applications, network performance measuring tools (e.g. network monitoring and traffic management applications), clickstream analysis tools, automobile traffic monitoring, and the like.

Communications subsystem 924 may also be configured to output the structured and/or unstructured data feeds 926, event streams 928, event updates 930, and the like to one or more databases that may be in communication with one or more streaming data source computers coupled to computer system 900.

Due to the ever-changing nature of computers and networks, the description of computer system 900 depicted in the figure is intended only as a specific example. Many other configurations having more or fewer components than the system depicted in the figure are possible. For example, customized hardware might also be used and/or particular elements might be implemented in hardware, firmware, software (including applets), or a combination. Further, connection to other computing devices, such as network input/output devices, may be employed. Based on the disclosure and teachings provided herein, other ways and/or methods to implement the various embodiments should be apparent.

As used herein, the terms “about” or “approximately” or “substantially” may be interpreted as being within a range that would be expected by one having ordinary skill in the art in light of the specification. By way of example, these terms may imply a 10% variation above or below a stated value (i.e., “approximately 50” would imply a range between 45 and 55).

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A method of measuring layer thickness uniformity on semiconductor wafers, the method comprising:
receiving an image of a portion of a wafer by a computer system, wherein the wafer includes a plurality of alternating layers of a first material and a second material;
determining, by the computer system, pixel intensities across the plurality of alternating layers in the image;
fitting the pixel intensities to a model that is descriptive of a trend in the pixel intensities; and
determining a thickness for a first layer of the wafer based on the model.

2. The method of claim 1, wherein the pixel intensities are based on an average of pixel intensities along an axis perpendicular to the plurality of alternating layers.

3. The method of claim 1, further comprising normalizing the model by removing background that can be modeled linearly.

4. The method of claim 3, wherein determining the thickness for a first layer of the wafer is based on determining a difference between half height points of a peak in the model.

5. The method of claim 1, wherein the thickness of the first material is between 60 and 70 nanometers.

6. The method of claim 1, wherein determining the thickness of the first layer has a maximum measurement error of 0.05 nanometers.

7. The method of claim 1, wherein the model comprises a hyper-Gaussian model.

8. The method of claim 1, wherein the model comprises a hyper-Lorentzian model.

9. The method of claim 1, wherein the method does not require determining thickness of the first layer by counting pixels along the thickness of the first layer.

10. A system, comprising:
a memory configured to store computer-executable instructions; and
one or more processors in communication with the memory and configured to access the memory and execute the computer-executable instructions to:
receive an image of a portion of a wafer;
determine pixel intensities across the plurality of alternating layers in the image;
fit the pixel intensities to a model that is descriptive of a trend in the pixel intensities; and
determine a thickness for a first layer of the wafer based on the model.

11. The system of claim 10, wherein fitting the pixel intensities to the model generates a model of a series of peaks and valleys.

12. The system of claim 10, wherein the first material is silicon, and the second material is silicon germanium.

13. The system of claim 10, wherein the thickness of the first material is between 8 and 10 nanometers.

14. The system of claim 10, wherein the portion of the wafer is a lamella extracted from the wafer, and wherein the image is an image of an entirety of the lamella.

15. The system of claim 10, wherein fitting the pixel intensities to the model includes determining a best model based on nonlinear regression.

16. The system of claim 10, wherein the system does not require multiple images obtained by transmission electron microscopy.

17. One or more non-transitory computer-readable media comprising computer-executable instructions that, when executed by one or more processors of a computer system, cause the one or more processors to perform operations comprising:
receiving an image of a portion of a wafer, wherein the wafer includes a plurality of alternating layers of a first material and a second material;
determining pixel intensities across the plurality of alternating layers in the image;
fitting the pixel intensities to a model that is descriptive of a trend in the pixel intensities; and
determining a thickness for a first layer of the wafer based on the model.

18. The one or more non-transitory computer-readable media of claim 17, wherein the computer-executable instructions cause the one or more processors to perform further operations comprising adjusting parameters of a deposition process based at least in part on the thickness for the first layer of the wafer.

19. The one or more non-transitory computer-readable media of claim 17, wherein the computer-executable instructions cause the one or more processors to perform further operations comprising determining a second thickness for a second layer of the wafer.

20. The one or more non-transitory computer-readable media of claim 19, wherein the second layer is adjacent to the first layer.
